(19) United States
(12) Patent Application Publication
(10) Pub. No.: US 2026/0363113 A1
(43) Pub. Date: Nov. 12, 2026

(54) SUBSTRATE STRUCTURE AND MANUFACTURING METHOD THEREOF

(71) Applicant: SILICONWARE PRECISION INDUSTRIES CO., LTD., Taichung City (TW)

(72) Inventor: Chan-Yu YEH, Taichung City (TW)

(73) Assignee: SILICONWARE PRECISION INDUSTRIES CO., LTD., Taichung City (TW)

(21) Appl. No.: 19/673,996

(22) Filed: May 11, 2026

(30) Foreign Application Priority Data
May 12, 2025 (TW) 114117724

(51) Int. Cl. H10W 70/65; H10W 70/05; H10W 70/68; H10W 70/692

(52) U.S. Cl. CPC H10W 70/65; H10W 70/096; H10W 70/68; H10W 70/692

(57) ABSTRACT

A substrate structure and a method of manufacturing the substrate structure are provided. A plurality of glass modules are disposed on a carrier, and a channel is spaced between any two adjacent glass modules. An insulating layer is formed on the carrier to cover the plurality of glass modules. A wiring layer is then formed on the insulating layer, and the carrier is subsequently removed. Then, a singulation process is performed along the channel. This arrangement prevents a cutting tool from contacting the plurality of glass modules, thereby avoiding cracking or burr defects.

### BACKGROUND

### 1. Technical Field

The present disclosure relates to a semiconductor structure, and more particularly, to a substrate structure and a manufacturing method thereof.

### 2. Description of Related Art

In the early development of semiconductor packaging, lead frames were used as carriers for chips, primarily due to their advantages of lower manufacturing costs and higher reliability. However, with the rapid development of the electronics industry, electronic products are increasingly focused on high performance, high functionality, and high speed. Therefore, to meet the demands for high integration and miniaturization in semiconductor devices, current packaging processes are gradually replacing lead frames with package substrates featuring high-density and fine-pitch wiring.

With the increasing demand for heterogeneous integration in the aforementioned electronic products, a large number of chips are disposed adjacent to each other on a package substrate. However, to accommodate all the chips, the planar dimensions of the package substrate must be increased. However, in semiconductor packaging processes, temperature cycling or stress changes frequently occur (such as during reflow oven processes or drop tests). Large-sized package substrates are prone to uneven stress distribution due to differences in the coefficient of thermal expansion (CTE) across different regions, thereby leading to warpage. This warpage may easily cause electrical connection failures (such as open circuits) between subsequent semiconductor chips and the package substrate, thereby resulting in product scrap and reduced yield.

To this end, the industry has considered integrating glass materials into package substrates, hoping to mitigate warping issues via the low coefficient of thermal expansion characteristic of glass materials. However, integrating glass materials into the composite material formed by the package substrate may easily lead to microburrs or chipping on the glass material during subsequent packaging processes (such as cutting steps). These microburrs or chipping issues are difficult to detect, thereby severely impacting the reliability of subsequent products.

Therefore, how to overcome the aforementioned problems of the prior art has become an urgent issue to be addressed.

### SUMMARY

In view of the above-mentioned deficiencies of the prior art, the present disclosure provides a substrate structure, which comprises: an insulating layer having a first side and a second side opposite to the first side; a glass module embedded in the second side of the insulating layer, the glass module having a first surface, a second surface opposite to the first surface, and side surfaces adjacent to the first surface and the second surface, wherein the second surface of the glass module is exposed from the second side of the insulating layer, and the side surfaces of the glass module are spaced apart from adjacent side edges of the insulating layer; and a wiring layer formed on the first side of the insulating layer.

The present disclosure also provides a method of manufacturing a substrate structure, and the method comprises: disposing a plurality of glass modules on a carrier, with a channel spaced between any two adjacent ones of the plurality of glass modules, wherein each of the plurality of glass modules has a first surface, a second surface opposite to the first surface, and side surfaces adjacent to the first surface and the second surface, wherein each of the plurality of glass modules is connected to and disposed on the carrier via the second surface; forming an insulating layer on the carrier, wherein the insulating layer has a first side and a second side opposite to the first side, and the insulating layer is disposed on the carrier via the second side to cover the plurality of glass modules and the channel spaced between any two adjacent ones of the plurality of glass modules; forming a wiring layer on the insulating layer; removing the carrier to expose the second surface of each of the plurality of glass modules and the insulating layer located within the channel; and performing a singulation process along the channel to form a plurality of the substrate structures.

In the aforementioned substrate structure and method, the present disclosure further comprises: forming a first circuit layer on the first surface of each of the plurality of glass modules.

In the aforementioned substrate structure and method, the present disclosure further comprises: forming a second circuit layer on the second surface of each of the plurality of glass modules.

In the aforementioned substrate structure and method, the present disclosure further comprises: forming protective layers on the wiring layer and the second circuit layer, respectively.

In the aforementioned substrate structure and method, the wiring layer is a redistribution layer.

In the aforementioned substrate structure and method, the second surface of each of the plurality of glass modules is flush with the second side of the insulating layer.

In the aforementioned substrate structure and method, during the singulation process, a cutting tool does not contact the plurality of glass modules.

As can be seen from the above, in the substrate structure and manufacturing method thereof of the present disclosure, a plurality of glass modules are embedded in the insulating layer to improve the warpage problem of the substrate structure. Furthermore, a cutting channel is reserved between the adjacent glass modules. Accordingly, after forming circuit layers on the glass modules and a wiring layer on the insulating layer, the cutting tool only passes through the insulating layer during the singulation process, thereby avoiding cutting the glass modules and preventing cracking or burr defects.

### BRIEF DESCRIPTION OF THE DRAWINGS

FIG. 1 to FIG. 6 are cross-sectional schematic views illustrating a method of manufacturing a substrate structure according to the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “above,” “lower,” “under,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

Please refer to FIG. 1 to FIG. 6, which are cross-sectional schematic views illustrating a method of manufacturing a substrate structure 1 according to the present disclosure.

As shown in FIG. 1, a carrier 100 is provided, and a plurality of glass modules 10 are disposed on the carrier 100, wherein adjacent glass modules 10 are separated by a channel L (e.g., any two adjacent glass modules 10 are separated by the channel L). In an embodiment, the glass module 10 is made of a glass dielectric material.

The glass module 10 has a first surface 10a, a second surface 10b opposite to the first surface 10a, and side surfaces 10c adjacent to the first surface 10a and the second surface 10b. The glass module 10 is connected to and disposed on the carrier 100 via the second surface 10b.

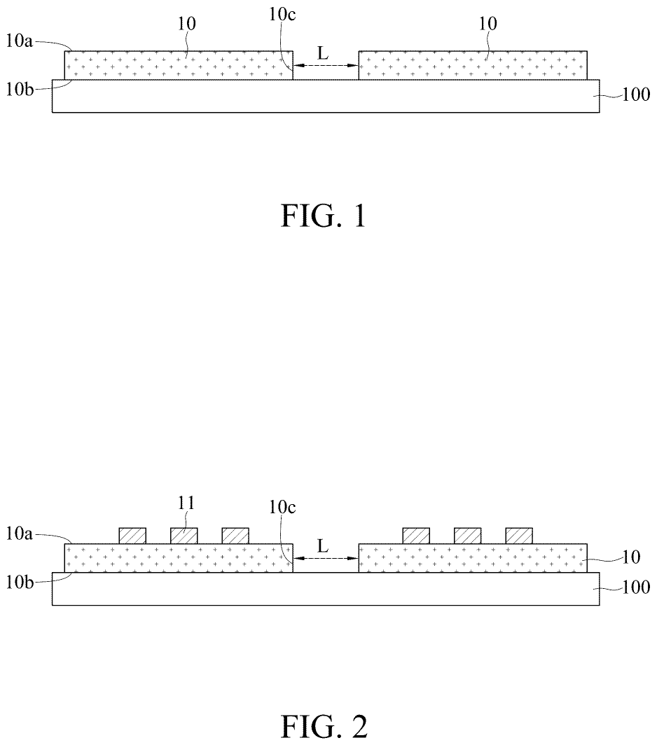

As shown in FIG. 2, a first circuit layer 11 is formed on the first surface 10a of the glass module 10. In an embodiment, the first circuit layer 11 is made of copper.

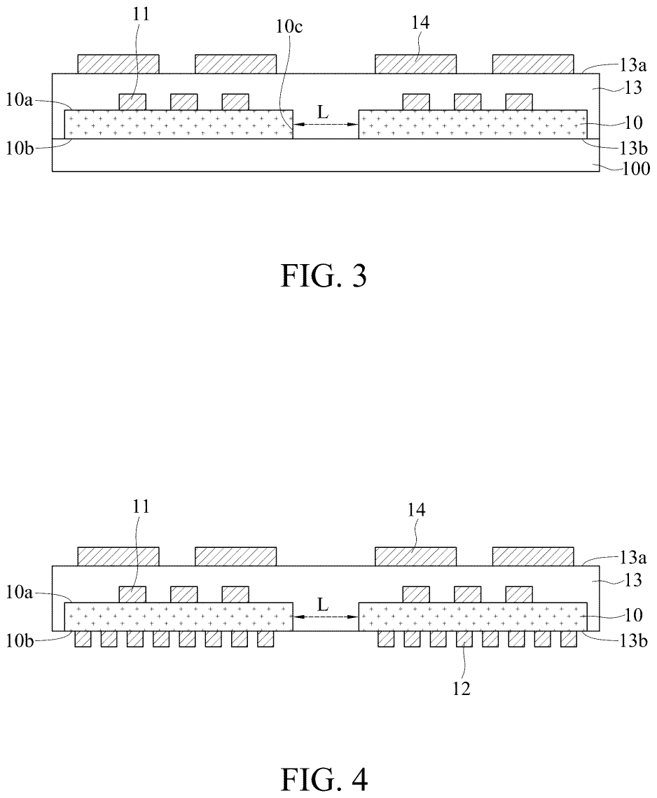

As shown in FIG. 3, via a circuit build-up process, an insulating layer 13 and a wiring layer 14 are formed on the carrier 100 (and the glass modules 10), and the wiring layer 14 is electrically connected to the first circuit layer 11.

In an embodiment, the wiring layer 14 is, for example, a redistribution layer (RDL), and the wiring layer 14 is made of copper. The insulating layer 13 is made of polybenzoxazole (PBO), polyimide (PI), prepreg (PP), or other dielectric materials.

The insulating layer 13 has a first side 13a and a second side 13b opposite to the first side 13a. The insulating layer 13 is disposed on the carrier 100 via the second side 13b so as to cover the plurality of glass modules 10 and the channel L spaced between adjacent glass modules 10. The wiring layer 14 is formed on the first side 13a of the insulating layer 13.

As shown in FIG. 4, the carrier 100 is removed to expose the second surface 10b of each of the plurality of glass modules 10 and the insulating layer 13 disposed within the channel L, wherein the second surface 10b of each of the plurality of glass modules 10 is flush with the second side 13b of the insulating layer 13. Then, a second circuit layer 12 is formed on the second surface 10b of each of the plurality of glass modules 10. In an embodiment, the second circuit layer 12 is made of copper.

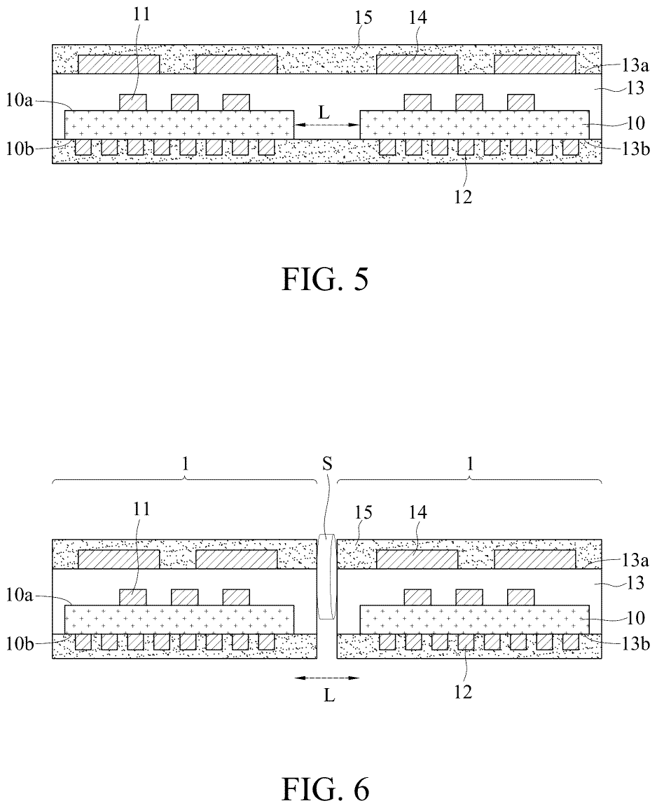

As shown in FIG. 5, protective layers 15 are respectively formed on the wiring layer 14 and the second circuit layer 12. In an embodiment, the protective layer 15 is, for example, a solder resist layer made of a solder resist material.

As shown in FIG. 6, a singulation process is performed along the channel L to form a plurality of the substrate structures 1.

During the singulation process, a cutting tool S only contacts the protective layers 15 and the insulating layer 13 (e.g., resin materials) which have relatively low elastic coefficient/modulus. As a result, the stress applied is reduced, and the cutting tool S can be prevented from contacting the glass modules 10 and causing cracking or burr defects in the glass modules 10.

Through the aforementioned process, the present disclosure further provides a substrate structure 1, which comprises: an insulating layer 13 having a first side 13a and a second side 13b opposite to the first side 13a; a glass module 10 having a first surface 10a, a second surface 10b opposite to the first surface 10a, and side surfaces 10c adjacent to the first surface 10a and the second surface 10b, wherein the glass module 10 is embedded in the second side 13b of the insulating layer 13, and the second surface 10b is exposed from the second side 13b; a first circuit layer 11 formed on the first surface 10a of the glass module 10 and embedded in the insulating layer 13; a second circuit layer 12 formed on the second surface 10b of the glass module 10 and exposed from the insulating layer 13; and a wiring layer 14 formed on the first side 13a of the insulating layer 13.

The insulating layer 13 is made of, for example, polybenzoxazole, polyimide, prepreg, or other dielectric materials.

The glass module 10 is made of, for example, a glass dielectric material.

The first circuit layer 11, the second circuit layer 12, and the wiring layer 14 are made of, for example, copper.

The second surface 10b of the glass module 10 is flush with the second side 13b of the insulating layer 13.

The side surfaces 10c of the glass module 10 are embedded in the insulating layer 13 and are spaced apart from adjacent side edges of the insulating layer 13 (e.g., the side surfaces 10c of the glass module 10 are kept at a distance from the adjacent side edges of the insulating layer 13).

The substrate structure 1 further comprises: protective layers 15 respectively formed on the wiring layer 14 and the second circuit layer 12, wherein the protective layers 15 are, for example, solder resist layers made of a solder resist material.

To sum up, in the substrate structure and manufacturing method thereof of the present disclosure, a plurality of glass modules are embedded in the insulating layer to improve the warpage problem of the substrate structure. Furthermore, a cutting channel is reserved between the adjacent glass modules. Accordingly, after forming circuit layers on the glass modules and a wiring layer on the insulating layer, the cutting tool only passes through the insulating layer during the singulation process, thereby avoiding cutting the glass modules and preventing cracking or burr defects.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A substrate structure, comprising:
an insulating layer having a first side and a second side opposite to the first side;
a glass module embedded in the second side of the insulating layer, the glass module having a first surface, a second surface opposite to the first surface, and side surfaces adjacent to the first surface and the second surface, wherein the second surface of the glass module is exposed from the second side of the insulating layer, and the side surfaces of the glass module are spaced apart from adjacent side edges of the insulating layer; and
a wiring layer formed on the first side of the insulating layer.

2. The substrate structure of claim 1, further comprising: a first circuit layer formed on the first surface of the glass module and embedded in the insulating layer.

3. The substrate structure of claim 1, further comprising: a second circuit layer formed on the second surface of the glass module and exposed from the insulating layer.

4. The substrate structure of claim 3, further comprising: protective layers respectively formed on the wiring layer and the second circuit layer.

5. The substrate structure of claim 1, wherein the wiring layer is a redistribution layer.

6. The substrate structure of claim 1, wherein the second surface of the glass module is flush with the second side of the insulating layer.

7. A method of manufacturing a substrate structure, comprising:
disposing a plurality of glass modules on a carrier, with a channel spaced between any two adjacent ones of the plurality of glass modules, wherein each of the plurality of glass modules has a first surface, a second surface opposite to the first surface, and side surfaces adjacent to the first surface and the second surface, wherein each of the plurality of glass modules is connected to and disposed on the carrier via the second surface;
forming an insulating layer on the carrier, wherein the insulating layer has a first side and a second side opposite to the first side, and the insulating layer is disposed on the carrier via the second side to cover the plurality of glass modules and the channel spaced between any two adjacent ones of the plurality of glass modules;
forming a wiring layer on the insulating layer;
removing the carrier to expose the second surface of each of the plurality of glass modules and the insulating layer located within the channel; and
performing a singulation process along the channel to form a plurality of the substrate structures.

8. The method of claim 7, further comprising: forming a first circuit layer on the first surface of each of the plurality of glass modules.

9. The method of claim 7, further comprising: forming a second circuit layer on the second surface of each of the plurality of glass modules.

10. The method of claim 9, further comprising: forming protective layers on the wiring layer and the second circuit layer, respectively.

11. The method of claim 7, wherein the wiring layer is a redistribution layer.

12. The method of claim 7, wherein the second surface of each of the plurality of glass modules is flush with the second side of the insulating layer.

13. The method of claim 7, wherein during the singulation process, a cutting tool does not contact the plurality of glass modules.
